(19) United States
(12) Patent Application Publication
(10) Pub. No.: US 2021/0136891 A1
(43) Pub. Date: May 6, 2021

(54) COLOR TEMPERATURE CONTROL SYSTEM

(71) Applicant: NICHIA CORPORATION, Anan-shi (JP)

(72) Inventors: Junichi EGUCHI, Itano-gun (JP); Kenji ASAI, Naruto-shi (JP)

(73) Assignee: NICHIA CORPORATION, Anan-shi (JP)

(21) Appl. No.: 17/086,278

(22) Filed: Oct. 30, 2020

(30) Foreign Application Priority Data
Oct. 30, 2019 (JP) 2019-197339
May 7, 2020 (JP) 2020-081805

(51) Int. Cl. H05B 45/28; H01L 33/50

(52) U.S. Cl. CPC H05B 45/28; H01L 33/502

(57) ABSTRACT

A lighting device including a first light emitting device that emits light of first chromaticity coordinates and has a high melanopic ratio, a second light emitting device that emits light of second chromaticity coordinates, and a third light emitting device that emits light of third chromaticity coordinates and has a low melanopic ratio, wherein light in a range from a first temperature to a second temperature on the black body radiation locus is included in a triangular area surrounded by a straight line connecting the first chromaticity coordinates and the second chromaticity coordinates, a straight line connecting the second chromaticity coordinates and the third chromaticity coordinates, and a straight line connecting the third chromaticity coordinates and the first chromaticity coordinates, in the chromaticity diagram of the CIE1931 color system.

### CROSS-REFERENCE TO RELATED PATENT APPLICATION

This application claims priority to Japanese Patent Application No. 2019-197339, filed on Oct. 30, 2019, and Japanese Patent Application No. 2020-081805, filed on May 7, 2020, the entire disclosures of which are hereby incorporated by references in their entirety.

### BACKGROUND

The present disclosure relates to a lighting device and a color temperature control system.

Lighting is an indispensable element in buildings such as offices, factories, commercial facilities, and houses. Various places of activity of people, such as work, shopping, and gathering, are lit up by lighting.

Conventionally, for such indoor lighting, good luminous efficiency and high color rendering properties are important parameters for evaluating the performance of the lighting. Japanese Patent Publication No. 2018-129492 discloses a light emitting device having a high color rendering property with an average color rendering index of 90 or more.

In recent years, in order to set up a human working environment, there is also a tendency to attach importance to consideration of influence on a human body. For example, in the certification system called WELL Standard (Well Building Standard) defined by IWBI (International WELL Building Institute), buildings such as offices are evaluated based on multiple items such as air, water, food, light, and comfort, and certification is given by satisfying the criteria.

For example, with respect to the features for light in the WELL Standard, consideration for the visual environment, consideration for the circadian, and consideration for the glare of electric light and solar light are regarded as essential evaluation items, and the color rendering property is not essential but is an additional item. In such a manner, lighting for lighting up an indoor space where a person works is expected to take into consideration the influence on a human body, but not limited to have good color rendering property.

An object of the present disclosure is to provide a lighting in consideration of influence on a human body.

### SUMMARY

According to an embodiment of the present disclosure, a lighting device, controlling a color temperature in a range of correlated color temperatures from a first temperature to a second temperature that is higher than the first temperature by 2,000 K, the lighting device including a first light emitting device, a second light emitting device, and a third light emitting device. The first light emitting device emits light having a light emission color of first chromaticity coordinates in which values of x and y in the first chromaticity coordinates are equal to or less than values of x and y at the second temperature on the black body radiation locus, respectively, in a chromaticity diagram of the CIE1931 color system. The second light emitting device emits light having a light emission color of second chromaticity coordinates in which a value of x in the second chromaticity coordinates is equal to or more than a value of x at the first temperature on the black body radiation locus, in the chromaticity diagram of the CIE1931 color system. The third light emitting device emits light having a light emission color of third chromaticity coordinates in which a value of x in the third chromaticity coordinates is a first value, and, when a straight line passing through the first temperature and the second temperature on the black body radiation locus is represented by a function of x and y, a value of y in the third chromaticity coordinates is a second value larger than a value of y obtained by substituting the first value for the value of x in the function, in the chromaticity diagram of the CIE1931 color system Light in a range from the first temperature to the second temperature on the black body radiation locus is included in a triangular area surrounded by a straight line connecting the first chromaticity coordinates and the second chromaticity coordinates, a straight line connecting the second chromaticity coordinates and the third chromaticity coordinates, and a straight line connecting the third chromaticity coordinates and the first chromaticity coordinates, in the chromaticity diagram of the CIE1931 color system. At least the first light emitting device, the second light emitting device, and the third light emitting device are used to control color temperature of the light in the range from the first temperature to the second temperature. The value of a melanopic ratio is 1.0 or more when light having a correlated color temperature of 5,000 K on the black body radiation locus is emitted. The change amount of a value of the melanopic ratio is 0.4 or more when the color temperature of light is changed in a range of correlated color temperatures of 3,000 K to 5,000 K on the black body radiation locus.

According to an embodiment of the present disclosure, a color temperature control system, including one or more of the lighting devices according to the above disclosure, and an information processing device that is communicably connected to a controller associated with the one or more of the lighting devices and adjusts light in a range of correlated color temperatures from a first temperature to a second temperature by the one or more of the lighting devices, the information processing device includes a color temperature determination unit, and a transmission unit. The color temperature determination unit determines a control command to the controller for controlling the controller to adjust light emitted from the one or more of the lighting devices. The transmission unit transmits the control command determined by the color temperature determination unit to the controller. The control range of color temperature performed by the information processing device is in an area surrounded by a straight line connecting the first temperature and the second temperature on the black body radiation locus, and a set of points located at twice the distance from points on the straight line to points on the black body radiation locus at the same correlated color temperatures, which is obtained at all the points on the straight line between the first temperature and the second temperature, and is in the inside of an outer frame, but not on the outer frame of the area, at least in any correlated color temperature between the first temperature and the second temperature, in the chromaticity diagram of the CIE1931 color system.

According to an embodiment of the present disclosure, a color temperature control system, including one or more of the lighting devices according to the above disclosure, and an information processing device that is communicably connected to a controller associated with the one or more of the lighting devices and adjusts light in a range of correlated color temperatures from a first temperature to a second temperature by the one or more of the lighting devices, the information processing device comprising includes a color temperature determination unit and a transmission unit. The color temperature determination unit determines a control command to the controller for controlling the controller to adjust light emitted from the one or more of the lighting devices. The transmission unit transmits the control command determined by the color temperature determination unit to the controller. The control range of color temperature performed by the information processing device between the first temperature and the second temperature is in a color deviation of ±0.001, in the chromaticity diagram of the CIE1931 color system.

According to the present disclosure, a lighting in consideration of influence on a human body can be provided, compared to conventional lightings.

### BRIEF DESCRIPTION OF THE DRAWINGS

FIG. 1 is a graph showing curves of a circadian response and a visual sensitivity response.

FIG. 2 is a perspective view of the lighting device according to an embodiment of the present disclosure as seen from the light emitting surface side.

FIG. 3 is a perspective view of the lighting device according to the embodiment as seen from the installation surface side.

FIG. 4 is a plan view for illustrating a light emitting surface of the lighting device according to the embodiment.

FIG. 5 is a schematic constitution diagram of a light emitting device included in the lighting device according to the embodiment.

FIG. 6 shows examples of light emission spectra of first light emitting devices used in the lighting device according to the embodiment.

FIG. 7 shows examples of light emission spectra of second light emitting devices used in the lighting device according to the embodiment.

FIG. 8 shows examples of light emission spectra of third light emitting devices used in the lighting device according to the embodiment.

FIG. 9 is a chromaticity diagram of the CIE1931 color system showing chromaticity coordinates of first to third light emitting devices constituting an example of the lighting device according to the embodiment.

FIG. 10 is a chromaticity diagram of the CIE1931 color system showing chromaticity coordinates of first to third light emitting devices constituting an example of the lighting device according to the embodiment.

FIG. 11 is a chromaticity diagram of the CIE1931 color system showing chromaticity coordinates of first to third light emitting devices constituting an example of the lighting device according to the embodiment.

FIG. 12 is a chromaticity diagram of the CIE1931 color system showing chromaticity coordinates of first to third light emitting devices constituting an example of the lighting device according to the embodiment.

FIG. 13 is a chromaticity diagram of the CIE1931 color system showing chromaticity coordinates of first to third light emitting devices constituting an example of the lighting device according to the embodiment.

FIG. 14 is a graph comparing a relative melanopic ratio of the lighting devices of Examples 1 to 5 according to the embodiment and a relative melanopic ratio of a comparative lighting device.

FIG. 15 is a constitution diagram illustrating an example of the color temperature control system according to the embodiment.

FIG. 16A is a schematic constitution diagram showing another example of the light emitting device according to the embodiment.

FIG. 16B is a schematic constitution diagram showing another example of the light emitting device according to the embodiment.

FIG. 16C is a schematic constitution diagram showing another example of the light emitting device according to the embodiment.

### DETAILED DESCRIPTION

First, the effect of lighting on a human body will be described.

As an example of the WELL Standard described in the background, a design for lighting in consideration of circadian is required. Here, considering circadian means considering circadian rhythm.

The circadian rhythm of human beings is longer than one day and is approximately 25 hours, and if it is not adjusted to one day, that is, a 24 hours cycle, the rhythm cycle deviates from one day. Thus, light plays an important role as a synchronization factor for adjusting to 24 hours. The human biological clock is adjusted to 24 hours by being exposed to the sunlight, which naturally causes people to live in the rhythm of one day, such as waking up in the morning and going to sleep at night.

That is, in order to live in the rhythm of 24 hours, the human body has a synchronization function utilizing light. Specifically, there is a very small area called the suprachiasmatic nucleus in the hypothalamus of the brain. The suprachiasmatic nucleus plays the role of the biological clock that controls circadian rhythm. As a cell for giving a light signal to the suprachiasmatic nucleus, there is an intrinsically photosensitive Retinal Ganglion Cell (hereinafter, referred to as “ipRGC”) on the retina.

The ipRGC contains a photoreceptor protein called melanopsin, and it has been clarified that melanopsin is involved in the photic entrainment of the circadian rhythm. Melanopsin has light absorption characteristics according to the wavelength of light, and the peak is in the vicinity of 480 to 490 nm.

Melanopsin is also involved in secretion or suppression of melatonin which is a sleep promoting hormone, and it is considered that, for example, the secretion of melatonin is suppressed by increasing the amount of stimulation to the ipRGC. Normally, the peak of melatonin secretion in the body comes at night, and the secretion of melatonin promotes sleep. Thus, the secretion of melatonin is suppressed during the day.

In the WELL Standard, an Equivalent Melanopic Lux (hereinafter, referred to as “EML”) is introduced in order to evaluate whether or not the design for lighting is in consideration of circadian. The EML is calculated by the following formula (1).

EML=Illuminance×Meranopic Ratio (1)

The melanopic ratio (hereinafter, referred to as “MR”) in the formula (1) is calculated by the following formula (2).

$$Meranopic Ratio = \frac{{\sum }_{730}^{380} Light \times Circadian}{{\sum }_{730}^{380} Light \times Visual} \times 1.218 \qquad ( 2 )$$

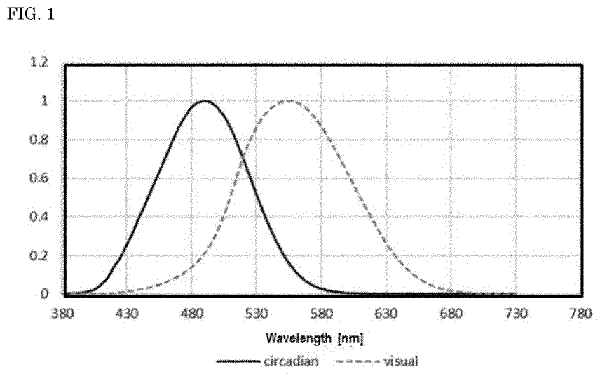

In the formula (2), the “Light” represents a spectral distribution of light from an lighting device, the “Circadian” represents a circadian response based on spectral sensitivity characteristics of the melanopsin having a peak in the vicinity of 480 nm to 490 nm, and the “Visual” represents a visual sensitivity response. FIG. 1 is a graph showing curves of a circadian response and a visual sensitivity response.

As seen from the formula (1), there are two possible ways of increasing the EML value: increasing the illuminance or increasing the MR. Further, it can be seen that the circadian rhythm characteristic is more dependent on the MR than the illuminance. Therefore, it is preferable to consider the MR value in consideration of the circadian rhythm. Further, based on the circadian response, the light emission intensity in a wavelength range of approximately 470 nm to 490 nm is considered to be a wavelength range particularly contributing to the secretion control of melatonin.

Embodiments for carrying out the present disclosure will be hereunder described with reference to the drawings. The embodiments described below are intended to embody the technical idea of the present disclosure and are not intended to limit the present disclosure. Further, in the following description, the same name or symbol represents the same or equivalent member, and detailed description thereof will be omitted as appropriate. The sizes and positional relationships of members shown in each drawing may be exaggerated for clarity of explanation. The relationships between color names and chromaticity coordinates, and the relationships between wavelength ranges of light and color names of monochromic light are in accordance with Japanese Industrial Standard (JIS) Z8110.

### Embodiment

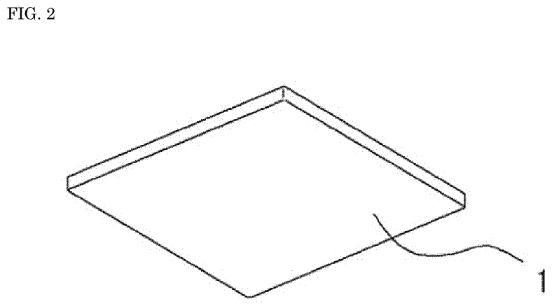

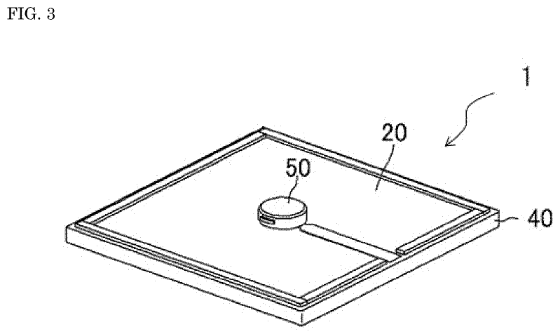

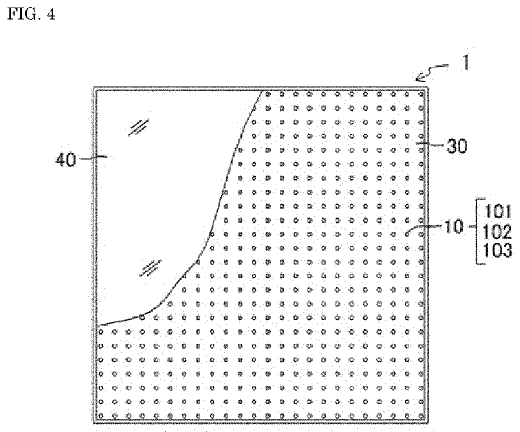

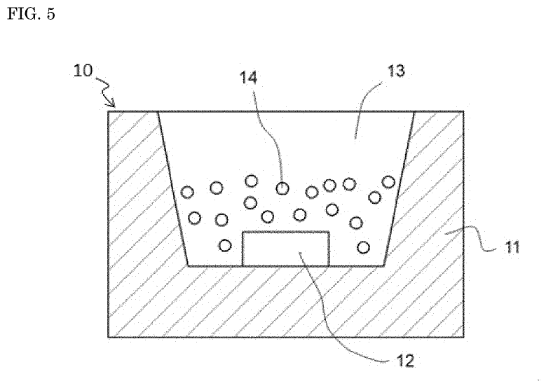

The lighting device according to the embodiment will be described. FIG. 2 is a perspective view of a lighting device 1 as seen from the light emitting surface side. FIG. 3 is a perspective view of the lighting device 1 as seen from the installation surface side (the side opposite to the light emitting surface side). FIG. 4 is a diagram showing the light emitting surface of the lighting device 1, and shows an internal structure except for a part of a cover 40 of the lighting device 1. FIG. 5 is a cross-sectional view showing an outline of a light emitting device 10 included in the lighting device 1.

The lighting device 1 includes at least three light emitting devices 10 that respectively emit lights with different chromaticity coordinates based on the chromaticity diagram of the CIE1931 color system (hereinafter, simply referred to as “chromaticity diagram”). The three light emitting devices 10 are respectively referred to as a first light emitting device 101, a second light emitting device 102, and a third light emitting device 103 to distinguish them.

By using the three light emitting devices 10 installed in the lighting device 1, the irradiated light can be changed in a predetermined color temperature range. The color temperature range controlled using the lighting device 1 is described as a range from the first temperature to the second temperature. The color temperature range needs to be within the maximum color temperature range at which the lighting device 1 can change the color temperature, but does not need to be the maximum range. However, the light emitted from the lighting device 1 is controlled within a color temperature range of 2,000 K or more.

For example, the first temperature may be set to 2,700 K and the second temperature may be set to 6,500 K (i.e., the color temperature can be changed within a color temperature range of 3,800 K). Alternatively, for example, the first temperature may be set to 3,000 K and the second temperature may be set to 5,000 K (the color temperature can be changed within a color temperature range of 2,000 K).

Three light emitting devices 10 each having different chromaticity coordinates with appropriate characteristics are combined in the lighting device 1, so that the light along the black body radiation locus can be emitted with consideration of the circadian rhythm when controlling the color temperature.

In the chromaticity diagram of the CIE1931 color system, the chromaticity coordinates of the light emitted from the first light emitting device 101 are defined as first chromaticity coordinates, the chromaticity coordinates of the light emitted from the second light emitting device 102 are defined as second chromaticity coordinates, and the chromaticity coordinates of the light emitted from the third light emitting device 103 are defined as third chromaticity coordinates.

In order to control the light from the first temperature to the second temperature along the black body radiation locus, light emitted from the lighting device 1 includes light in a range from at least the first temperature to the second temperature, that is, light on the black body radiation locus in which the color deviation duv from the black body radiation locus measured according to JIS Z8725 is 0.00, is within a triangular area connecting three points of the first chromaticity coordinates, the second chromaticity coordinates, and the third chromaticity coordinates.

The three light emitting devices 10 satisfy the following conditions.

As for the first light emitting device 101, the values of x and y in the first chromaticity coordinates are equal to or less than the values of x and y at the second temperature on the black body radiation locus, respectively, in the chromaticity diagram of the CIE1931 color system. Preferably, the value of x in the first chromaticity coordinates is smaller than the value of x at the second temperature on the black body radiation locus, and the difference between the value of x in the first chromaticity coordinates and the value of x at the second temperature on the black body radiation locus is 0.1 or more. In the chromaticity diagram of the CIE1931 color system, the value of x in the first chromaticity coordinates is in a range of 0.1 or more and 0.2 or less. In the chromaticity diagram of the CIE1931 color system, the value of y in the first chromaticity coordinates is in a range of 0.2 or more and 0.3 or less. A light emitting device having a high MR value is employed as the first light emitting device 101.

As for the second light emitting device 102, the value of x in the second chromaticity coordinates is equal to or more than the value of x at the first temperature on the black body radiation locus in the chromaticity diagram of the CIE1931 color system In the chromaticity diagram of the CIE1931 color system, the value of x in the second chromaticity coordinates is in a range of 0.45 or more and 0.6 or less. In the chromaticity diagram, of the CIE1931 color system the value of y in the second chromaticity coordinates is equal to or less than the value of y at the first temperature on the black body radiation locus. In the chromaticity diagram of the CIE1931 color system, the value of y in the second chromaticity coordinates is in a range of 0.3 or more and 0.5 or less. A light emitting device having a low MR value is employed as the second light emitting device 102.

As for the third light emitting device 103, the third chromaticity coordinates are located in the +y direction with respect to the straight line passing through the first temperature and the second temperature on the black body radiation locus in the chromaticity diagram of the CIE1931 color system. That is, when the value of x in the third chromaticity coordinates is a first value, the value of y in the third chromaticity coordinates is larger than the value of y obtained by substituting the first value for the value of x in the function representing the straight line. In this example, in the case in which the value of x in the third chromaticity coordinates is the first value, the value of y in the third chromaticity coordinates is referred to as a second value. In the third chromaticity coordinates, the value of x is equal to or less than the value of x at the second temperature on the black body radiation locus, and the value of y is equal to or more than the value of y at the second temperature on the black body radiation locus.

As for the third light emitting device 103, the value of x in the third chromaticity coordinates is in a range of 0.1 or more and 0.6 or less in the chromaticity diagram of the CIE1931 color system. The value of x in the third chromaticity coordinates can be in a range of 0.4 or more and 0.5 or less, in the chromaticity diagram of the CIE1931 color system. The value of x in the third chromaticity coordinates can be in a range of 0.3 or more and 0.4 or less, in the chromaticity diagram of the CIE1931 color system. The value of y in the third chromaticity coordinates is in a range of 0.3 or more and 0.6 or less in the chromaticity diagram. A light emitting device having an MR value lower than that of the first light emitting device 101 and higher than that of the second light emitting device 102, is employed as the third light emitting device 103.

The high MR value described in the first light emitting device 101 means that the MR value is a value close to 2.00 or a value larger than 2.00. The MR value of the first light emitting device 101 is preferably 2.00 or more, more preferably 2.50 or more, and even more preferably 2.80 or more. The higher the MR value, the more suppressed the secretion of melatonin. The MR value of the first light emitting device 101 is 3.00 or less. However, the upper limit value can exceed 3.00.

The low MR value described in the second light emitting device 102 means that the MR value is a value close to 0.40 or a value smaller than 0.40. The MR value of the second light emitting device 102 is preferably 0.40 or less, more preferably 0.30 or less, and even more preferably 0.25 or less. The lower the MR value, the more stimulated the secretion of melatonin. The MR value of the second light emitting device 102 is 0.0 or more.

In the chromaticity diagram of the CIE1931 color system, in the case in which the value of x in the third chromaticity coordinates is 0.1 or more smaller than the middle of the value of x in the first chromaticity coordinates and the value of x in the second chromaticity coordinates, a light emitting device having an MR value of 1.0 or more can be employed as the third light emitting device 103. On the other hand, in the case in which the value of x in the third chromaticity coordinates is larger than the middle value and a difference between the value of x in the third chromaticity coordinates and the middle value is 0.1 or more, a light emitting device having an MR value of 0.5 or less can be employed. Further, in the case of being less than ±0.1 from the middle value, a light emitting device having an MR value in a range of 0.5 or more and 1.0 or less can be employed. The MR value of the third light emitting device 103 is preferably 2.00 or more.

The lighting device 1 emitting light as a whole has a configuration in which a plurality of these three light emitting devices 10 are disposed, or four or more light emitting devices 10 including these three light emitting devices 10 and other light emitting device(s).

The lighting device 1 includes a base plate 20, a substrate 30, at least one light emitting device 10, a cover 40, and an installation member 50. The lighting device 1 is connected to a controller that adjusts the light emitted from the lighting device 1. The controller can be incorporated in the lighting device 1.

The controller is equipped with a driver program for adjusting the light emitted from the lighting device 1. The program is installed in a memory of the controller, such as a ROM or a RAM, and is expanded by a processor such as a CPU to execute processing.

In the lighting device 1, the substrate 30 is attached to the base plate 20. A plurality of light emitting devices 10 are mounted on the substrate 30. The plurality of light emitting devices 10 are electrically connected through wiring, and electric power is supplied from an external power source to control light emission from the light emitting devices 10.

The cover 40 is attached to the base plate 20 so as to cover the plurality of light emitting devices 10 arranged on the substrate 30. The installation member 50 is provided on the surface (i.e., installation surface) of the base plate 20 opposite to the surface on which the light emitting devices 10 are arranged. The lighting device 1 is installed on a support member by the installation member 50. The support member is, for example, a ceiling, a wall, or a stand. FIG. 3 shows an example in which the installation member 50 is installed on the ceiling.

In the lighting device 1, the first light emitting device 101, the second light emitting device 102, and the third light emitting device 103 are successively arranged as the light emitting devices 10. In the example of FIG. 4, the plurality of light emitting devices 10 are arranged in a matrix, and the first light emitting device 101, the second light emitting device 102, and the third light emitting device 103 are successively arranged by one column (or one row) each. These light emitting devices can be alternately arranged in units that are not in row or column units. For example, these light emitting devices can be alternately arranged in units of one light emitting device or in units of a plurality of light emitting devices. The first light emitting device 101, the second light emitting device 102, and the third light emitting device 103 each include a light emitting element and a fluorescent material.

The light emitting device 10 includes a molded body 11, at least one light emitting element 12, and a wavelength conversion member 13. As the light emitting element 12, a nitride semiconductor having a light emission peak in a range of 410 nm or more and 490 nm or less can be employed. As the wavelength conversion member 13, a fluorescent material 14 that is excited by light emitted from the light emitting element 12 and emits light having a different wavelength can be employed. The molded body 11 is a housing in which the light emitting element 12 and the wavelength conversion member 13 are housed. In this specification, interpretation of the “fluorescent material” includes a “fluorescent phosphor”.

The first light emitting device 101 and the second light emitting device 102 each contain a fluorescent material having a mutually different composition as a main fluorescent material. The main fluorescent material means the fluorescent material contained the most in the wavelength conversion member 13 of the light emitting device 10. By employing a light emitting device including a different main fluorescent material, the difference between the MR value at a high color temperature and the MR value at a low color temperature can be made larger than in a case of employing a light emitting device having the same main fluorescent material.

The light emitting element 12 is not limited to a nitride semiconductor. The light emitting element 12 can be a light emitting element having a light emission peak outside the above range. As the light emitting element, an LED, an organic electroluminescent display (organic EL), a laser diode, or the like can be used. The molded body 11 can not be provided.

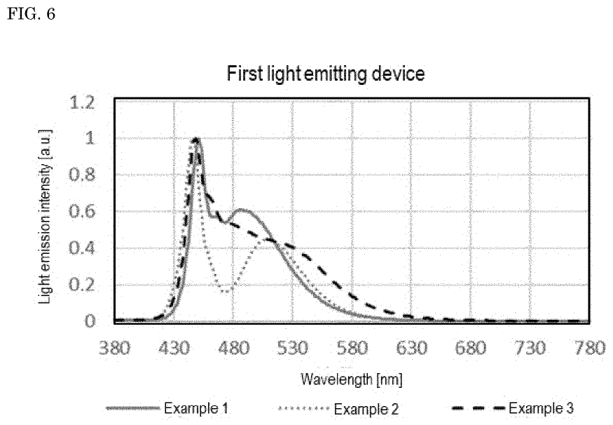

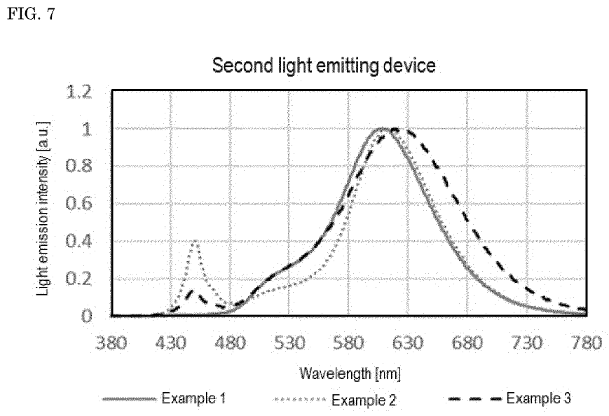

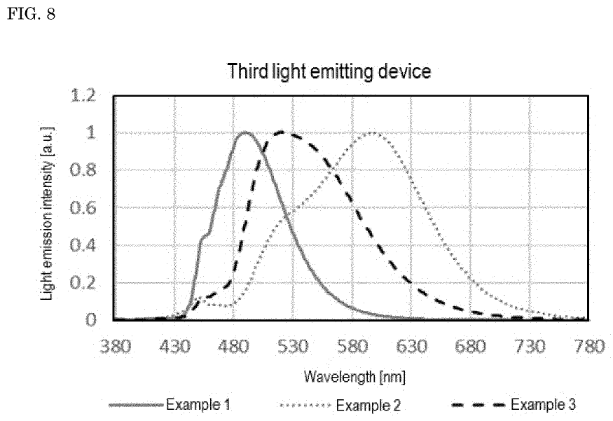

Hereinafter, specific examples of light emitting devices to be employed as the first light emitting device 101, the second light emitting device 102, and the third light emitting device 103 will be described. FIG. 6 shows a light emission spectrum of each Example of the first light emitting device 101. FIG. 7 shows a light emission spectrum of each Example of the second light emitting device 102. FIG. 8 shows a light emission spectrum of each Example of the third light emitting device 103.

<First Light Emitting Device 101, Example 1>

As the first light emitting device 101, for example, a light emitting device including: a light emitting element 12, which is a nitride semiconductor, having a light emission peak in a range of 410 nm or more and 470 nm or less, and preferably having a light emission peak in a range of 420 nm or more and 460 nm or less; and a wavelength conversion member 13 containing an alkaline earth metal aluminate fluorescent material having a composition represented by a formula of Sr₄Al₁₄O₂₅:Eu as a main fluorescent material and having a light emission peak at 495 nm, can be used. In the first light emitting device 101, the x value of the first chromaticity coordinates is 0.149 and they value thereof is 0.223 in the chromaticity diagram of the CIE1931 color system. The MR value is 2.85.

The luminous efficiency is 122 lm/W.

### First Light Emitting Device 101, Example 2

As the first light emitting device 101, for example, a light emitting device including: a light emitting element 12, which is a nitride semiconductor, having a light emission peak in a range of 410 nm or more and 490 nm or less; and a wavelength conversion member 13 containing a chlorosilicate fluorescent material having a composition represented by a formula of Ca₈Mg(SiO₄)₄Cl₂:Eu as a main fluorescent material and having a light emission peak at 510 nm, can be used. In the first light emitting device 101, the x value of the first chromaticity coordinates is 0.167 and the y value thereof is 0.246 in the chromaticity diagram of the CIE1931 color system. The MR value is 2.07. The luminous efficiency is 145 lm/W.

### First Light Emitting Device 101, Example 3

As the first light emitting device 101, for example, a light emitting device including: a light emitting element 12, which is a nitride semiconductor, having a light emission peak in a range of 410 nm or more and 470 nm or less; and a wavelength conversion member 13 containing a rare earth aluminate fluorescent material having a composition represented by a formula of Lu₃(Al,Ga)₅O₁₂:Ce as a main fluorescent material and having a light emission peak at 496 nm, can be used. In the first light emitting device 101, the x value of the first chromaticity coordinates is 0.191 and the y value thereof is 0.265 in the chromaticity diagram of the CIE1931 color system. The MR value is 1.94. The luminous efficiency is 148 lm/W.

### Second Light Emitting Device 102, Example 1

As the second light emitting device 102, for example, a light emitting device including: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃Al₅O₁₂:Ce, a rare earth aluminate fluorescent material having a composition represented by a formula of Lu₃Al₅O₁₂:Ce, and a silicon nitride fluorescent material having a composition represented by a formula of (Sr,Ca)AlSiN₃:Eu, as a main fluorescent material, can be used. In the second light emitting device 102, the x value of the second chromaticity coordinates is 0.539, the y value thereof is 0.443, the correlated color temperature is 2,000 K, and the color deviation duv is +0.01, in the chromaticity diagram of the CIE1931 color system. The MR value is 0.23. The luminous efficiency is 168 lm/W.

### Second Light Emitting Device 102, Example 2

As the second light emitting device 102, for example, a light emitting device including: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃Al₅O₁₂:Ce, a rare earth aluminate fluorescent material having a composition represented by a formula of Lu₃Al₅O₁₂:Ce, and a silicon nitride fluorescent material having a composition represented by a formula of (Sr,Ca)AlSiN₃:Eu, as a main fluorescent material, can be used. In the second light emitting device 102, the x value of the second chromaticity coordinates is 0.505, the y value thereof is 0.359, the correlated color temperature is 2,000 K, and the color deviation duv is −0.02, in the chromaticity diagram of the CIE1931 color system. The MR value is 0.35. The luminous efficiency is 144 lm/W.

### Second Light Emitting Device 102, Example 3

As the second light emitting device 102, for example, a light emitting device including: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃Al₅O₁₂:Ce, a rare earth aluminate fluorescent material having a composition represented by a formula of Lu₃Al₅O₁₂:Ce, and a silicon nitride fluorescent material having a composition represented by a formula of (Sr,Ca)AlSiN₃:Eu, as a main fluorescent material, can be used. In the second light emitting device 102, the x value of the second chromaticity coordinates is 0.524, the y value thereof is 0.416, the correlated color temperature is 2,000 K, and the color deviation duv is 0.00, in the chromaticity diagram of the CIE1931 color system. The MR value is 0.28. The luminous efficiency is 131 lm/W.

### Third Light Emitting Device 103, Example 1

As the third light emitting device 103, for example, a light emitting device including: a light emitting element 12, which is a nitride semiconductor, having a light emission peak in a range of 410 nm or more and 470 nm or less, and preferably having a light emission peak in a range of 420 nm or more and 460 nm or less; and a wavelength conversion member 13 containing an alkaline earth metal aluminate fluorescent material having a composition represented by a formula of Sr₄Al₁₄O₂₅:Eu as a main fluorescent material and having a light emission peak at approximately 495 nm, can be used. In the third light emitting device 103, the x value of the third chromaticity coordinates is 0.145 and the y value thereof is 0.354 in the chromaticity diagram of the CIE1931 color system. The MR value is 2.32. The luminous efficiency is 151 lm/W.

### Third Light Emitting Device 103, Example 2

As the third light emitting device 103, for example, a light emitting device including: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃Al₅O₁₂:Ce, a rare earth aluminate fluorescent material having a composition represented by a formula of Lu₃Al₅O₁₂:Ce, and a silicon nitride fluorescent material having a composition represented by a formula of (Sr,Ca)AlSiN₃:Eu, as a main fluorescent material, can be used. In the third light emitting device 103, the x value of the third chromaticity coordinates is 0.467, the y value thereof is 0.471, the correlated color temperature is 3,000 K, and the color deviation duv is +0.02, in the chromaticity diagram of the CIE1931 color system. The MR value is 0.38. The luminous efficiency is 204 lm/W.

### Third Light Emitting Device 103, Example 3

As the third light emitting device 103, for example, a light emitting device including: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃(Al,Ga)₅O₁₂:Ce as a main fluorescent material and having a light emission peak at approximately 496 nm, can be used. In the third light emitting device 103, the x value of the third chromaticity coordinates is 0.331 and the y value thereof is 0.548 in the chromaticity diagram of the CIE1931 color system. The MR value is 0.76. The luminous efficiency is 242 lm/W.

Next, the lighting device 1 constituted by including the above-mentioned first light emitting device 101, the second light emitting device 102, and the third light emitting device 103, will be exemplified. As a comparison object with the lighting device 1, the lighting device described below (hereinafter, referred to as “comparative lighting device”) is employed. The comparative lighting device is selected from the viewpoint of good luminous efficiency and high color rendering properties conventionally expected for lighting.

### <Comparative Lighting Device>

The comparative lighting device is constituted of two light emitting devices respectively having correlated color temperatures of 2,700 K and 6,500K, and having a color deviation of 0.00. Each of the light emitting devices includes: a light emitting element 12, which is a nitride semiconductor, having a light emission peak in a range of 410 nm or more and 490 nm or less; and a wavelength conversion member 13 containing a rare earth aluminate fluorescent material having a composition represented by a formula of Y₃Al₅O₁₂:Ce, a rare earth aluminate fluorescent material having a composition represented by a formula of Lu₃Al₅O₁₂:Ce, and a silicon nitride fluorescent material having a composition represented by a formula of (Sr,Ca)AlSiN₃:Eu. The average color rendering index (hereinafter, referred to as “Ra”) is 80 or more, and the luminous efficiency is 180 lm/W to 200 lm/W at the correlated color temperature in a range of 2,700 K to 6,500 K. The details are shown in Table A below.

TABLE A

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2762 | 0.001 | 0.44 | 184 | 82 |
| 3000 | 3066 | −0.003 | 0.52 | 189 | 84 |
| 3500 | 3570 | −0.005 | 0.62 | 195 | 85 |
| 4000 | 4066 | −0.005 | 0.70 | 197 | 85 |
| 4500 | 4563 | −0.005 | 0.77 | 198 | 85 |
| 5000 | 5053 | −0.004 | 0.82 | 198 | 85 |
| 5700 | 5738 | −0.001 | 0.89 | 197 | 84 |
| 6500 | 6520 | 0.001 | 0.95 | 195 | 83 |

### Lighting Device 1, Example 1

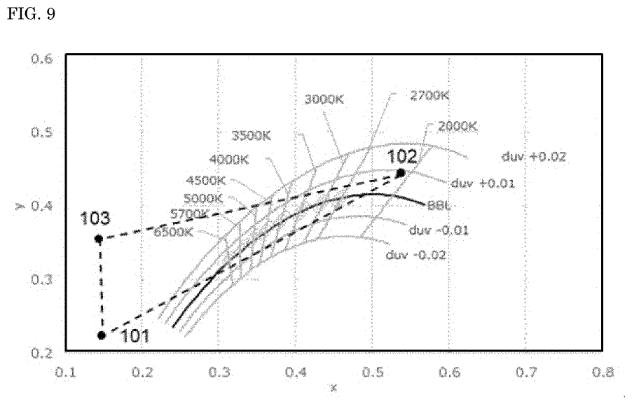

The lighting device 1 of Example 1 is constituted of the first light emitting device 101, the second light emitting device 102, and the third light emitting device 103 of each Example 1. Table 1 shows a result of which the lighting device 1 is evaluated by using the items in the above Table A. The chromaticity diagram of the CIE1931 color system showing a relationship among the first to third chromaticity coordinates, the color temperature changeable range (triangle connecting three points), and the black body radiation locus, in the lighting device 1 of Example 1 is shown in FIG. 9.

TABLE 1

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2706 | 0.000 | 0.55 | 167 | 85 |
| 3000 | 3005 | 0.000 | 0.66 | 167 | 86 |
| 3500 | 3511 | 0.000 | 0.81 | 166 | 84 |
| 4000 | 4020 | 0.000 | 0.93 | 164 | 83 |
| 4500 | 4533 | 0.000 | 1.03 | 162 | 82 |
| 5000 | 5037 | 0.000 | 1.11 | 160 | 81 |
| 5700 | 5744 | 0.000 | 1.21 | 157 | 80 |
| 6500 | 6559 | 0.000 | 1.30 | 154 | 80 |

As described above, in the lighting device 1 of Example 1, the MR change amount in the correlated color temperature range of 2,700 K to 6,500 K is 0.75, which is larger than that of the comparative lighting device. Also, the MR change amount in the range of 3,000 to 5,000 K is 0.45, which is larger than that of the comparative lighting device. Further, the MR value at each of the same color temperatures is higher than that of the comparative lighting device. Here, the same target color temperatures are used for comparing the lighting devices. There are differences between the target color temperatures and actual result color temperatures, but they are allowed, and the target color temperature is employed as the color temperature in the present disclosure. The MR value of the lighting device 1 of Example 1 is 1.0 or more when light having a correlated color temperature of 5,000 K on the black body radiation locus (the color deviation duv is 0.000) is emitted. The MR change amount of the lighting device 1 of Example 1 is 0.4 or more when the color temperature of light is changed in a range of correlated color temperatures of 3,000 K to 5,000 K on the black body radiation locus.

The luminous efficiency of the lighting device 1 of Example 1 is slightly inferior to that of the comparative lighting device. The luminous efficiency at each of the color temperatures in the range of 2,700 K to 6,500 K as well as the range of 3,000 K to 5,000 K achieves 160 [lm/W] in each color temperature range, but not 170 [lm/W]. The color rendering property is at substantially the same level as that of the comparative lighting device. The Ra achieves 80 at each color temperature range, but not 85.

### Lighting Device 1, Example 2

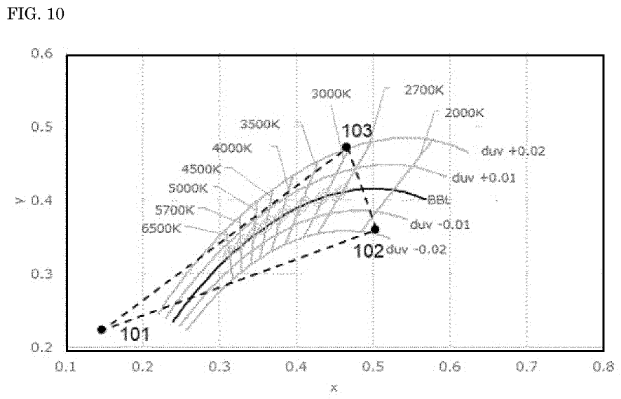

The lighting device 1 of Example 2 is constituted of the first light emitting device 101 of Example 1, and the second light emitting device 102 and the third light emitting device 103 of each Example 2. Table 2 shows a result of which the lighting device 1 is evaluated by using the items in the above Table A. The chromaticity diagram of the CIE1931 color system showing a relationship among the first to third chromaticity coordinates, the color temperature changeable range (triangle connecting three points), and the black body radiation locus, in the lighting device 1 of Example 2 is shown in FIG. 10.

TABLE 2

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2696 | 0.000 | 0.46 | 184 | 84 |
| 3000 | 3000 | 0.000 | 0.55 | 185 | 87 |
| 3500 | 3503 | 0.000 | 0.69 | 184 | 89 |
| 4000 | 4009 | 0.000 | 0.81 | 181 | 91 |
| 4500 | 4515 | 0.000 | 0.92 | 177 | 91 |
| 5000 | 5022 | 0.000 | 1.01 | 173 | 90 |
| 5700 | 5725 | 0.000 | 1.12 | 168 | 88 |
| 6500 | 6541 | 0.000 | 1.24 | 163 | 86 |

As described above, in the lighting device 1 of Example 2, the MR change amount in the correlated color temperature range of 2,700 K to 6,500 K is larger than that of the comparative lighting device. Also, the MR change amount in the range of 3,000 K to 5,000 K is larger than that of the comparative lighting device. Further, the MR value at each of the same color temperatures is higher than that of the comparative lighting device. The MR value of the lighting device 1 of Example 2 is 1.0 or more when light having a correlated color temperature of 5,000 K on the black body radiation locus (the color deviation duv is 0.000) is emitted. The MR change amount of the lighting device 1 of Example 2 is 0.4 or more when the color temperature of light is changed in a range of correlated color temperatures of 3,000 K to 5,000 K on the black body radiation locus.

In particular, in the lighting device 1 of Example 2, the MR value at a low color temperature (first color temperature) is not much different from that of the comparative lighting device, and the difference is widened at a high color temperature (second color temperature). It can be said that the lighting device 1 of Example 2 is effective for the life rhythm in which the human body becomes active during the daytime and calms down after the evening.

The luminous efficiency of the lighting device 1 of Example 2 is inferior to that of the comparative lighting device, but is superior to that of the lighting device 1 of Example 1. The luminous efficiency at each of the color temperatures in the range of 2,700 K to 6,500 K as well as the range of 3,000 K to 5,000 K achieves 170 [lm/W] in each color temperature range, but not 180 [lm/W]. The color rendering property of the lighting device 1 of Example 2 is superior to those of the comparative lighting device and the lighting device 1 of Example 1. The Ra achieves 85 or more at each color temperature range, but not 90. When the color temperature of light is changed in a range of correlated color temperatures of 3,000 K to 5,000 K on the black body radiation locus (the color deviation duv is 0.000), the average color rendering index of the lighting device 1 of Example 2 reaches 85, and the luminous efficiency [lm/W] of the lighting device 1 of Example 2 reaches 170.

### Lighting Device 1, Example 3

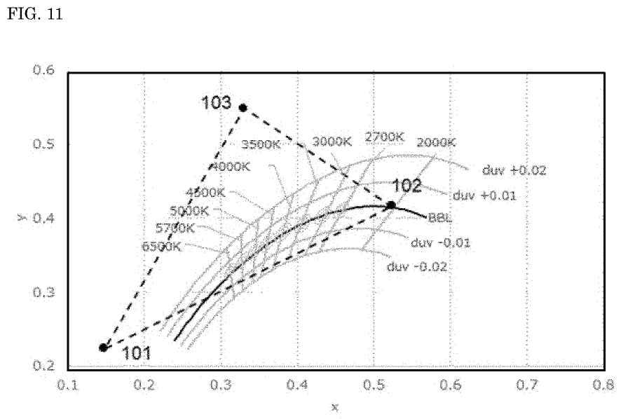

The lighting device 1 of Example 3 is constituted of the first light emitting device 101 of Example 1, and the second light emitting device 102 and the third light emitting device 103 of each Example 3. Table 3 shows a result of which the lighting device 1 is evaluated by using the items in the above Table A. The chromaticity diagram of the CIE1931 color system showing a relationship among the first to third chromaticity coordinates, the color temperature changeable range (triangle connecting three points), and the black body radiation locus, in the lighting device 1 of Example 3 is shown in FIG. 11.

TABLE 3

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2688 | 0.000 | 0.51 | 143 | 94 |
| 3000 | 2989 | 0.000 | 0.60 | 146 | 95 |
| 3500 | 3483 | 0.000 | 0.73 | 149 | 93 |
| 4000 | 3986 | 0.000 | 0.85 | 149 | 92 |
| 4500 | 4485 | 0.000 | 0.95 | 148 | 89 |
| 5000 | 4983 | 0.000 | 1.04 | 146 | 87 |
| 5700 | 5684 | 0.000 | 1.15 | 143 | 84 |
| 6500 | 6487 | 0.000 | 1.26 | 140 | 82 |

As described above, in the lighting device 1 of Example 3, the MR change amount in the correlated color temperature range of 2,700 K to 6,500 K is larger than that of the comparative lighting device. Also, the MR change amount in the range of 3,000 K to 5,000 K is larger than that of the comparative lighting device. Further, the MR value at each of the same color temperatures is higher than that of the comparative lighting device. The MR value of the lighting device 1 of Example 3 is 1.0 or more when light having a correlated color temperature of 5,000 K on the black body radiation locus (the color deviation duv is 0.000) is emitted. The MR change amount of the lighting device 1 of Example 3 is 0.4 or more when the color temperature of light is changed in a range of correlated color temperatures of 3,000 K to 5,000 K on the black body radiation locus.

The luminous efficiency of the lighting device 1 of Example 3 is inferior to that of the comparative lighting device. The luminous efficiency at each of the color temperatures in the range of 2,700 K to 6,500 K as well as the range of 3,000 K to 5,000 K achieves 140 [lm/W] in each color temperature range, but not 150 [lm/W]. The color rendering property of the lighting device 1 of Example 3 is superior to that of the comparative lighting device, and in particular, the Ra achieves 90 in the low color temperature range of 4,000 K or less. The difference in the color rendering property between the first color temperature and the second color temperature is larger than those of the other lighting devices 1.

### Lighting Device 1, Example 4

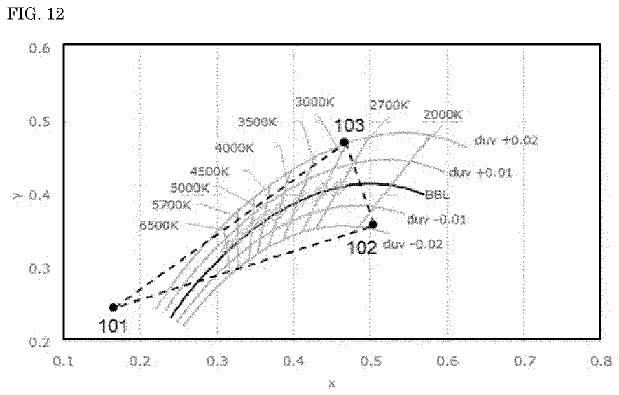

The lighting device 1 of Example 4 is constituted of the first light emitting device 101, the second light emitting device 102, and the third light emitting device 103 of each Example 2. Table 4 shows a result of which the lighting device 1 is evaluated by using the items in the above Table A. The chromaticity diagram of the CIE1931 color system showing a relationship among the first to third chromaticity coordinates, the color temperature changeable range (triangle connecting three points), and the black body radiation locus, in the lighting device 1 of Example 4 is shown in FIG. 12.

TABLE 4

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2697 | 0.000 | 0.45 | 185 | 84 |
| 3000 | 3005 | 0.000 | 0.52 | 187 | 86 |
| 3500 | 3513 | 0.000 | 0.63 | 187 | 90 |
| 4000 | 4017 | 0.000 | 0.73 | 185 | 92 |
| 4500 | 4529 | 0.000 | 0.81 | 182 | 94 |
| 5000 | 5042 | 0.000 | 0.89 | 179 | 94 |
| 5700 | 5759 | 0.000 | 0.98 | 174 | 94 |
| 6500 | 6568 | 0.000 | 1.07 | 169 | 94 |

As described above, in the lighting device 1 of Example 4, the MR change amount in the correlated color temperature range of 2,700 K to 6,500 K is larger than that of the comparative lighting device. Also, the MR change amount in the range of 3,000 K to 5,000 K is larger than that of the comparative lighting device. Further, the MR value at each of the same color temperatures is higher than that of the comparative lighting device. The MR value of the lighting device 1 of Example 4 is less than 1.0 when light having a correlated color temperature of 5,000 K on the black body radiation locus (the color deviation duv is 0.000) is emitted. The MR change amount of the lighting device 1 of Example 4 is 0.4 or more when the color temperature of light is changed in a range of correlated color temperatures of 3,000 K to 5,000 K on the black body radiation locus.

The lighting device 1 of Example 4 has characteristics similar to those of the lighting device 1 of Example 2. In the lighting device 1 of Example 4, similarly to the lighting device 1 of Example 2, the MR value at a low color temperature (first color temperature) is not much different from that of the comparative lighting device, and the difference is widened at a high color temperature (second color temperature). However, the difference at a high color temperature is smaller than that of the lighting device 1 of Example 2. On the other hand, the color rendering property at a high color temperature of 4,000 K or more is superior to that of the lighting device 1 of Example 2.

### Lighting Device 1, Example 5

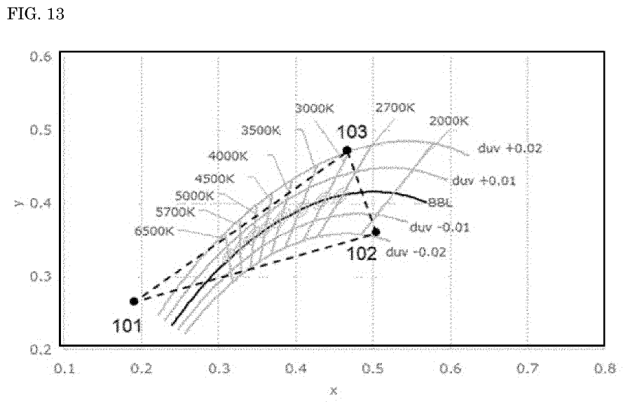

The lighting device 1 of Example 5 is constituted of the first light emitting device 101 of Example 3, and the second light emitting device 102 and the third light emitting device 103 of each Example 2. Table 5 shows a result of which the lighting device 1 is evaluated by using the items in the above Table A. The chromaticity diagram showing a relationship among the first to third chromaticity coordinates, the color temperature changeable range (triangle connecting three points), and the black body radiation locus, in the lighting device 1 of Example 5 is shown in FIG. 13.

TABLE 5

| Target | Result | | | | Average |
|---|---|---|---|---|---|
| color | color | | | | color |
| temper- | temper- | Color | Melanopic | Luminous | rendering |
| ature | ature | deviation | ratio | efficiency | index |
| Tcp [K] | Tcp [K] | duv | MR | [lm/W] | Ra |
| 2700 | 2700 | 0.000 | 0.45 | 185 | 83 |
| 3000 | 3002 | 0.000 | 0.53 | 186 | 86 |
| 3500 | 3506 | 0.000 | 0.65 | 186 | 88 |
| 4000 | 4014 | 0.000 | 0.75 | 184 | 90 |
| 4500 | 4519 | 0.000 | 0.85 | 181 | 92 |
| 5000 | 5031 | 0.000 | 0.93 | 177 | 93 |
| 5700 | 5740 | 0.000 | 1.03 | 172 | 95 |
| 6500 | 6561 | 0.000 | 1.13 | 167 | 94 |

As described above, in the lighting device 1 of Example 5, the MR change amount in the correlated color temperature range of 2,700 K to 6,500 K is larger than that of the comparative lighting device. Also, the MR change amount in the range of 3,000 K to 5,000 K is larger than that of the comparative lighting device. Further, the MR value at each of the same color temperatures is higher than that of the comparative lighting device. The lighting device 1 of Example 5 has characteristics almost similar to those of the lighting device 1 of Example 4. The MR value of the lighting device 1 of Example 5 is less than 1.0 when light having a correlated color temperature of 5,000 K on the black body radiation locus (the color deviation duv is 0.000) is emitted. The MR change amount of the lighting device 1 of Example 5 is 0.4 or more when the color temperature of light is changed in a range of correlated color temperatures of 3,000 K to 5,000 K on the black body radiation locus.

According to the lighting devices 1 described above with reference to Examples, the color temperature can be changed while changing the MR value in a greater range compared to conventional lighting devices. Accordingly, a lighting in consideration of influence on a human body can be provided.

In each of lighting devices 1 of Examples 1 to 5, the color temperature on the black body radiation locus can be changed, and when the color temperature of light is changed in the correlated color temperature range of 3,000 K to 5,000 K, the change amount in the value of the melanopic ratio (MR change amount) reaches at least 0.35. In the preferred lighting device 1, the change amount in the value of the melanopic ratio reaches at least 0.40. In the more preferred lighting device 1, the change amount in the value of the melanopic ratio reaches at least 0.45.

When the color temperature of light is changed in the correlated color temperature range of 2,700 K to 6,500 K, the change amount in the value of the melanopic ratio reaches at least 0.6. In the preferred lighting device 1, the change amount in the value of the melanopic ratio reaches at least 0.70. In the more preferred lighting device 1, the change amount in the value of the melanopic ratio reaches at least 0.75.

In the preferred lighting device 1, the melanopic ratio at a correlated color temperature of 3,000 K is 0.5 or less, and the melanopic ratio at a correlated color temperature of 5,000 K is 1.0 or more. In the lighting device 1 of Example 1 that realizes the largest value of the melanopic ratio, the value of the melanopic ratio at a correlated color temperature of 6,500 K reaches 1.3. That is, the value of a melanopic ratio of the lighting device 1 of Example 1 reaches 1.3 when light having a correlated color temperature of 6,500 K on the black body radiation locus is emitted. The melanopic ratio at a correlated color temperature of 6,500 K may be 1.3 or more.

In practice, when used as an lighting device, not only a comparison of the simple melanopic ratio values, but also a relationship with the luminous efficiency can be important. In the case in which the luminous efficiency is low, the luminous flux [lm] can be increased by increasing the input power [W] accordingly. However, if the control such as changing the input power according to the color temperature is performed within the color temperature range, the configuration of the devices becomes complicated. In addition, high satisfaction from user can be obtained by avoiding sacrifice in an energy-saving element as much as possible.

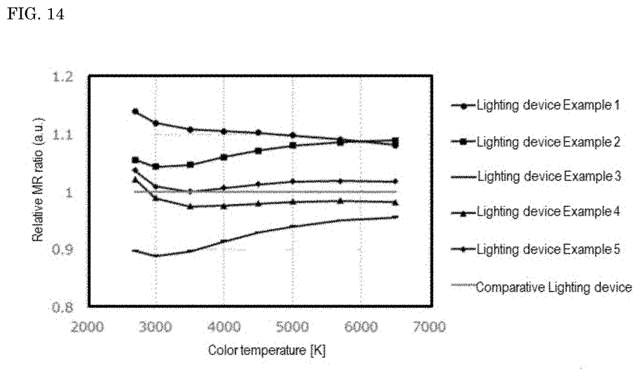

FIG. 14 is a graph comparing the comparative lighting device and the lighting devices 1 of Examples 1 to 5 using a value obtained by multiplying the MR value and the luminous efficiency. The multiplied value represents the relative relationship of the melanopic ratio in the lighting to be illuminated with a power of 1.0 [W]. Hereinafter, the value is referred to as a relative melanopic ratio. In order to facilitate comparison, the comparative lighting device is used as a reference.

As shown in FIG. 14, it is clearly seen that the lighting device 1 of Example 1 and the lighting device 1 of Example 2 have a larger relative melanopic ratio than that of the comparative lighting device. In the lighting device 1 of Example 1, the relative melanopic ratio is high at a low color temperature and decreases as the color temperature becomes higher. In the lighting device 1 of Example 2, the relative melanopic ratio is high at a high color temperature and increases as the color temperature becomes higher.

It can be said that the lighting device having a higher relative melanopic ratio at a high color temperature can provide light in consideration of circadian rhythm while considering energy efficiency. It can be said that the lighting device 1 of Example 2 has good performance as a lighting in consideration of circadian rhythm.

Next, the color temperature control performed using the lighting device 1 will be described.

The lighting device 1 is able to change color temperature using at least three light emitting devices 10, and the color temperature range includes the first temperature to the second temperature on the black body radiation locus. Thus, the color temperature change along the black body radiation locus can be performed with higher accuracy, compared with the comparative lighting device constituted with two light emitting devices.

Such control of color temperature change in the correlated color temperature range from the first temperature to the second temperature, can be realized by constituting a color temperature control system including a plurality of the lighting devices 1 and an information processing device 2 that is communicably connected to a controller for each of the lighting devices 1 and which adjusts light emitted from each lighting device 1 by controlling the controller.

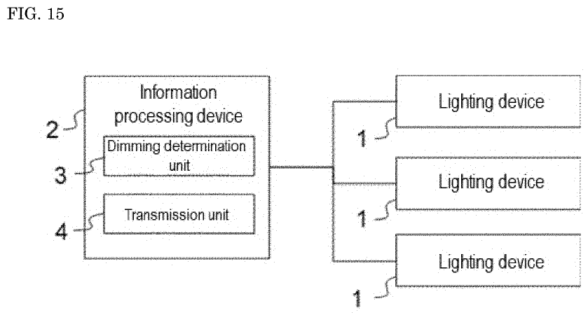

FIG. 15 is a diagram illustrating an example of constitution of the color temperature control system. The number of the lighting devices 1 can be one.

The information processing device 2 is a computer, a server device, or the like, and is a device capable of transmitting and receiving information via communication interface and executing arithmetic processing based on received information or recorded information. The information processing device 2 includes a processor such as a CPU for controlling arithmetic processing, a storage unit such as an HDD for storing programs and information, and a memory such as a ROM or a RAM that provides a storage area for developing a program and executing processing.

In the color temperature control system, the information processing device 2 includes a color temperature determination unit 3 that determines a control command to the controller in order to control light emitted from the lighting device 1. In the color temperature determination unit 3, when controlling color temperature in the correlated color temperature range from the first temperature to the second temperature, the light emission ratio of the light emitting device 10 is determined such that the light is irradiated with chromaticity coordinates closer to the black body radiation locus than a straight line connecting the first temperature and the second temperature on the black body radiation locus in the chromaticity diagram of the CIE1931 color system.

The information processing device 2 also includes a transmission unit 4 that transmits a control command to the controller. The transmission unit 4 transmits a control command to the controller such that the light emitting device 10 emits light with the determined light emission ratio. Thereby, the controller executes color temperature change based on the control command, and the color temperature change along the black body radiation locus can be performed with high accuracy.

In the chromaticity diagram of the CIE1931 color system, the control range of color temperature change by the information processing device 2 is within an area surrounded by a straight line connecting the first temperature and the second temperature on the black body radiation locus, and a set of points located at twice the distance from points on the straight line to points on the black body radiation locus at the same correlated color temperatures, which is obtained at all the points on the straight line between the first temperature and the second temperature. Also, the control range is within the inside of the outer frame, but not on the outer frame of the area, at least in any correlated color temperature between the first temperature and the second temperature. In the chromaticity diagram of the CIE1931 color system, the control range of color temperature change by the information processing device 2 is preferably within a color deviation duv of ±0.001 from the black body radiation locus between the first temperature and the second temperature.

In order to perform color temperature change in accordance with the circadian rhythm, the color temperature change is preferably performed corresponding to the change in the color temperature of sunlight. However, the color temperature change may not be accurately performed according to the change of sunlight. For example, the following color temperature change can be considered. In a day, the MR value is set to the minimum value of the day at 0:00 to 6:00, and changes to the maximum value at 6:00. Then, the MR value is maintained at the maximum value until 15:30, decreases with time from 15:30 to 19:00, and set to the minimum value after 19:00.

That is, the information processing device 2 controls the MR value so as to be the maximum at a predetermined time in the morning. Then, the information processing device 2 controls to decrease the MR value over a certain time from a predetermined time in the afternoon. Here, the MR value can be increased over a certain time from a predetermined time in the morning.

The MR value becomes maximum when the color temperature is maximized in the color temperature range. On the other hand, the MR value becomes minimum when the color temperature is minimized in the color temperature range.

Although the embodiments according to the present disclosure have been described above, the technical idea of the present disclosure is not limited to the specific embodiments described. For example, in the embodiments, the installation place of the color temperature control system according to the present disclosure is not necessarily limited to an office building.

The first light emitting device 101, the second light emitting device 102, and the third light emitting device 103 can be mounted on the substrate 30 as physically individual light emitting devices 10, or can be mounted by integrally forming a plurality of light emitting devices by appropriately determined number.

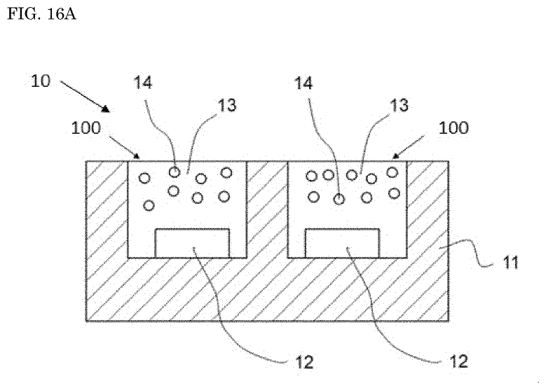

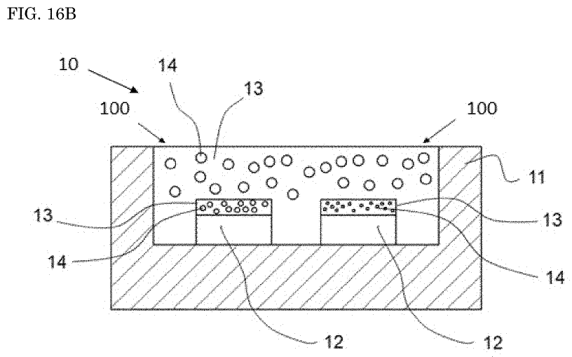

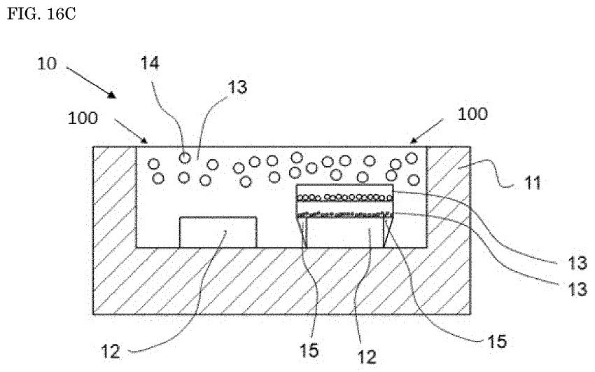

FIGS. 16A to 16C each show an exemplary light emitting device 10 in which a plurality of light emitting devices 100 are integrally formed. The plurality of light emitting devices 100 integrally formed includes two or more light emitting devices selected from the first light emitting device 101, the second light emitting device 102, and the third light emitting device 103.

FIG. 16A shows a structure of the light emitting device 10 in which two cavities are formed in one molded body 11, and among the plurality of light emitting devices 100, a light emitting element 12 and a wavelength conversion member 13 of one light emitting device 100, and a light emitting element 12 and a wavelength conversion member 13 of another light emitting device 100 are respectively disposed in the cavities.

FIG. 16B shows a structure of the light emitting device 10 in which one cavity is formed in one molded body 11, and among the plurality of light emitting devices 100, a light emitting element 12 and a wavelength conversion member 13 of one light emitting device 100, and a light emitting element 12 and a wavelength conversion member 13 of another light emitting device 100 are disposed in the cavity.

A wavelength conversion member 13 that contributes to light emission by one light emitting device 100 (one of the two light emitting devices 100 shown in the figure) and is not necessary for light emission by another light emitting device 100 (another one of the two light emitting devices 100 shown in the figure), is provided only around the light emitting element 12 of the one light emitting device 100. Similarly, a wavelength conversion member 13 that contributes to light emission by the other light emitting device 100 and is not necessary for light emission by the one light emitting device 100, is provided only around the light emitting element 12 of the other light emitting device 100. The wavelength conversion member 13 needed for light emission by the one light emitting device 100 and the other light emitting device 100 is provided so as to cover both the light emitting devices 100.

FIG. 16C shows a structure of the light emitting device 10 in which one cavity is formed in one molded body 11, and a light emitting element 12 and a wavelength conversion member 13 of one light emitting device 100, and a light emitting element 12 and one or more wavelength conversion members 13 of another light emitting device 100 are disposed in the cavity.

In comparison with FIG. 16B, a wavelength conversion member 13 that contributes to light emission by the one light emitting device 100 but is not necessary for light emission by the other light emitting device 100, is not provided in the one light emitting device 100. On the other hand, a wavelength conversion member 13 that contributes to light emission by the other light emitting device 100 but is not necessary for light emission by the one light emitting device 100, is provided only around the light emitting element 12 of the other light emitting device 100.

The wavelength conversion member 13 provided only around the light emitting element 12 of the other light emitting device 100 can be configured as a single layer or a plurality of layers. In each layer, fluorescent materials can be locally distributed on the lower surface. For example, such a wavelength conversion member 13 can be formed by attaching a sheet-shaped fluorescent material to a glass material.

One or more lateral surfaces of the light emitting element 12 of the other light emitting device 100 are covered with reflective layers 15. Thereby, the light emitted from the light emitting element 12 of the one light emitting device 100 is reflected by the reflective layers 15 before entering into the light emitting element 12 of the other light emitting device 100. Thus, the light emitted from the light emitting element 12 of the one light emitting device 100 is less likely to be subject to wavelength conversion by the wavelength conversion member 13 provided only around the light emitting element 12 of the other light emitting device 100.

As described above, the light emitting device 10 is configured as a plurality of light emitting devices 100 in which the first light emitting device 101, the second light emitting device 102, and the third light emitting device 103 are integrally formed. With such a configuration, the light emitting device 10 can be handled as one integrated package. Further, by controlling the light emitted from the light emitting device 10 as described above, the color temperature control system can be realized.

The present disclosure can be applied without necessarily and sufficiently providing all the constituent elements disclosed by the embodiments. Although a part of the constituent elements disclosed by the embodiments is not described in the scope of the claims, the present disclosure is applicable as long as it is within the flexibility of design to a person skilled in the art or in the technical field of the present disclosure, and thus the present disclosure is disclosed on the assumption that the present specification encompasses such constituent elements.

The color temperature control system and the lighting device described in the embodiments can be used in the field of lighting installed in an indoor space or the like.

What is claimed is:

1. A lighting device, controlling a color temperature in a range of correlated color temperatures from a first temperature to a second temperature that is higher than the first temperature by 2,000 K or more, the lighting device comprising:
a first light emitting device that emits light having a light emission color of first chromaticity coordinates in which values of x and y in the first chromaticity coordinates are equal to or less than values of x and y at the second temperature on the black body radiation locus, respectively, in a chromaticity diagram of the CIE1931 color system;
a second light emitting device that emits light having a light emission color of second chromaticity coordinates in which a value of x in the second chromaticity coordinates is equal to or more than a value of x at the first temperature on the black body radiation locus, in the chromaticity diagram of the CIE1931 color system; and
a third light emitting device that emits light having a light emission color of third chromaticity coordinates in which a value of x in the third chromaticity coordinates is a first value, and, when a straight line passing through the first temperature and the second temperature on the black body radiation locus is represented by a function of x and y, a value of y in the third chromaticity coordinates is a second value larger than a value of y obtained by substituting the first value for the value of x in the function, in the chromaticity diagram of the CIE1931 color system,
wherein light in a range from the first temperature to the second temperature on the black body radiation locus is included in a triangular area surrounded by a straight line connecting the first chromaticity coordinates and the second chromaticity coordinates, a straight line connecting the second chromaticity coordinates and the third chromaticity coordinates, and a straight line connecting the third chromaticity coordinates and the first chromaticity coordinates, in the chromaticity diagram of the CIE1931 color system;
at least the first light emitting device, the second light emitting device, and the third light emitting device are used to control the color temperature of the light in the range from the first temperature to the second temperature;
a value of a melanopic ratio is 1.0 or more when light having a correlated color temperature of 5,000 K on the black body radiation locus is emitted; and
a change amount of a value of the melanopic ratio is 0.4 or more when a color temperature of light is changed in a range of correlated color temperatures of 3,000 K to 5,000 K on the black body radiation locus.

2. The lighting device according to claim 1, wherein the value of x in the first chromaticity coordinates is smaller than the value of x at the second temperature on the black body radiation locus by 0.1 or more.

3. The lighting device according to claim 1, wherein, in the first chromaticity coordinates, the value of x is in a range of 0.1 or more and 0.2 or less, and the value of y is in a range of 0.2 or more and 0.3 or less.

4. The lighting device according to claim 1, wherein a value of the melanopic ratio is 1.3 or more when light having a correlated color temperature of 6,500 K on the black body radiation locus is emitted.

5. The lighting device according to claim 4, wherein the value of x in the third chromaticity coordinates is equal to or less than the value of x at the second temperature on the black body radiation locus, and the value of y in the third chromaticity coordinates is equal to or more than the value of y at the second temperature on the black body radiation locus.

6. The lighting device according to claim 4, wherein the first light emitting device and the third light emitting device each have a value of the melanopic ratio of 2.0 or more.

7. The lighting device according to claim 1,
wherein the value of y in the second chromaticity coordinates is equal to or less than the value of y at the first temperature on the black body radiation locus, and
the value of x in the third chromaticity coordinates is in a range of 0.4 or more and 0.5 or less, in the chromaticity diagram of the CIE1931 color system.

8. The lighting device according to claim 7, wherein, when the color temperature of light is changed in a range of correlated color temperatures of 3,000 to 5,000 K on the black body radiation locus, an average color rendering index 85 or more and a luminous efficiency 170 lm/W or more.

9. The lighting device according to claim 1, wherein the value of x in the third chromaticity coordinates is in a range of 0.3 or more and 0.4 or less, in the chromaticity diagram of the CIE1931 color system.

10. The lighting device according to claim 1, wherein the first light emitting device, the second light emitting device, and the third light emitting device each include a light emitting element and a fluorescent material.

11. The lighting device according to claim 1, wherein the first light emitting device includes an alkaline earth metal aluminate fluorescent material having a composition represented by Sr₄Al₁₄O₂₅:Eu as a main fluorescent material.

12. A color temperature control system, including one or more of the lighting devices according to claim 1, and an information processing device that is communicably connected to a controller associated with the one or more of the lighting devices and adjusts light in a range of correlated color temperatures from a first temperature to a second temperature by the one or more of the lighting devices, the information processing device comprising:
a color temperature determination unit that determines a control command to the controller for controlling the controller to adjust light emitted from the one or more of the lighting devices; and
a transmission unit that transmits the control command determined by the color temperature determination unit to the controller,
wherein the control range of color temperature change performed by the information processing device is in an area surrounded by a straight line connecting the first temperature and the second temperature on the black body radiation locus, and a set of points located at twice the distance from points on the straight line to points on the black body radiation locus at the same correlated color temperatures, which is obtained at all the points on the straight line between the first temperature and the second temperature, and is in the inside of an outer frame, but not on the outer frame of the area, at least in any correlated color temperature between the first temperature and the second temperature, in the chromaticity diagram of the CIE1931 color system.

13. A color temperature control system, including one or more of the lighting devices according to claim 1, and an information processing device that is communicably connected to a controller associated with the one or more of the lighting devices and adjusts light in a range of correlated color temperatures from a first temperature to a second temperature by the one or more of the lighting devices, the information processing device comprising:
a color temperature determination unit that determines a control command to the controller for controlling the controller to adjust light emitted from the one or more of the lighting devices; and
a transmission unit that transmits the control command determined by the color temperature determination unit to the controller,
wherein the control range of color temperature change performed by the information processing device between the first temperature and the second temperature is in a color deviation of ±0.001, in the chromaticity diagram of the CIE1931 color system.
